(19) United States
(12) Patent Application Publication
(10) Pub. No.: US 2022/0293511 A1
(43) Pub. Date: Sep. 15, 2022

(54) SEMICONDUCTOR DEVICE AND POWER AMPLIFIER

(71) Applicant: SUMITOMO ELECTRIC INDUSTRIES, LTD., Osaka (JP)

(72) Inventor: Koshi HAMANO, Osaka (JP)

(21) Appl. No.: 17/650,875

(22) Filed: Feb. 14, 2022

(30) Foreign Application Priority Data
Mar. 15, 2021 (JP) 2021-041319

(51) Int. Cl. H01L 23/528; H01L 27/088

(52) U.S. Cl. CPC H01L 23/528; H01L 27/088

(57) ABSTRACT

A semiconductor device includes a gate wiring line connected to an input wiring line, a first and second transistors disposed on both sides of the gate wiring line, and a signal combining wiring line. The signal combining wiring line includes a first output wiring line that extends on or above the first transistor over at least one source wiring line and at least one gate electrode and that is connected to drain wiring lines of the first transistor, a second output wiring line that extends on or above the second transistor over at least one source wiring line and at least one gate electrode and that is connected to drain wiring lines of the second transistor, a third output wiring line that connects the first and the second output wiring lines, and a fourth output wiring line that connects the third output wiring line to the output terminal.

### CROSS-REFERENCE TO RELATED APPLICATIONS

This application claims priority to Japanese Patent Application No. 2021-041319 filed on Mar. 15, 2021, the entire contents of which are incorporated herein by reference.

### BACKGROUND

### 1. Field of the Invention

The present disclosure relates to a semiconductor device and a power amplifier.

### 2. Description of the Related Art

A field effect transistor formed on a substrate such as a GaAs substrate and an SiC substrate can increase a gate width without increasing a layout size by forming what is called a multi-finger type gate electrode or a fishbone type gate electrode. In this case, shield electrodes are disposed between a gate transmission line wired from a gate pad to a gate electrode and respective drain electrodes, thereby improving a gain in a high-frequency region (for example, see Patent Document 1).

In addition, by providing a gate pad at the center of a transistor region and directly connecting a gate electrode to the gate pad, a delay of an electric signal between the gate electrodes is prevented (for example, see to Patent Document 2). Furthermore, by arranging the multi-finger type gate electrodes so as to be shifted in the extending direction of the gate electrodes, heat dissipation is improved without increasing the distance between the gate electrodes (for example, see Patent Document 3).

Here, a fishbone type gate electrode or a fishbone type transistor will be described. Fishbone indicates a fish bone. A fish has a backbone connecting a head and a tail fin, and thin bones such as ribs extending in opposite directions on a dorsal fin side and a ventral fin side that are substantially perpendicular to the backbone. A gate electrode structure, in which a gate wiring line corresponding to the backbone is located at the center line of the structure and gate electrodes corresponding to the thin bones are arranged on both sides of the gate wiring line such that the gate wiring line is interposed between the gate electrodes, is referred to as a fishbone type gate electrode. Further, a structure, in which a source region and a drain region are disposed on both sides of each of the gate electrodes such that the gate electrode is interposed between the source region and the drain region and a transistor cell is formed in each set of the gate electrode, the source region, and the drain region, is referred to as a fishbone type transistor. The gate width of the fishbone type transistor is the sum of the widths of the respective gate electrodes connected to the gate wiring line.

For example, in a power amplifier operating at a high frequency such as a millimeter wave band, it is required to improve output power rather than a gain. In order to improve the output power, it is necessary to reduce loss of the output signal. For example, in a transistor mounted on a power amplifier, it is necessary to minimize routing of wiring from a drain from which a signal is output to an output terminal.

### RELATED ART DOCUMENTS

### Patent Document

[Patent Document 1] Japanese Unexamined Patent Application Publication No. 4-125941
[Patent Document 2] Japanese Unexamined Patent Application Publication No. 6-5849
[Patent Document 3] International Publication WO 2018/020549

### SUMMARY

According to one aspect of this embodiment, a semiconductor device includes a gate wiring line that is connected to an input wiring line connected to an input terminal, the gate wiring line extending in a first direction, a first transistor and a second transistor disposed on both sides of the gate wiring line, along a second direction orthogonal to the first direction, and a signal combining wiring line that connects an output of the first transistor and an output of the second transistor to an output terminal. Each of the first transistor and the second transistor includes a plurality of gate electrodes connected to the gate wiring line, the plurality of gate electrodes extending in the second direction, one or more source regions and one or more drain regions arrayed in the first direction with each of the plurality of gate electrodes being interposed between a corresponding source region among the one or more source regions and a corresponding drain region among the one or more drain regions, one or more source wiring lines respectively disposed on the one or more source regions, the one or more source wiring lines being respectively connected to the one or more source regions, and one or more drain wiring lines respectively disposed on the one or more drain regions, the one or more drain wiring lines being respectively connected to the one or more drain regions. The signal combining wiring line includes a first output wiring line that extends on or above the first transistor in the first direction over at least one of the one or more source wiring lines and at least one of the plurality of gate electrodes, the first output wiring line being connected to the one or more drain wiring lines of the first transistor, a second output wiring line that extends on or above the second transistor in the first direction over at least one of the one or more source wiring lines and at least one of the plurality of gate electrodes, the second output wiring line being connected to the one or more drain wiring lines of the second transistor, a third output wiring line that connects one end of the first output wiring line in the first direction and one end of the second output wiring line in the first direction, and a fourth output wiring line that connects the third output wiring line to the output terminal.

According to at least one embodiment of the present disclosure, loss of an output signal can be reduced and output power can be increased by reducing the size of a signal combining wiring line connected to a drain which is an output of a transistor.

### BRIEF DESCRIPTION OF THE DIAGRAMS

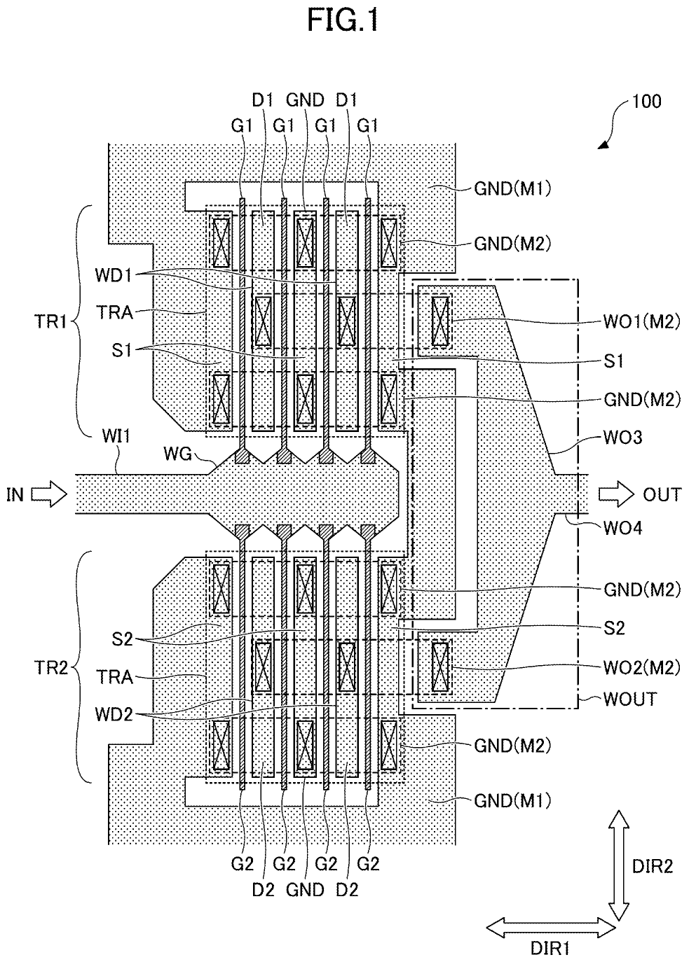

FIG. 1 is a layout diagram illustrating an example of a circuit configuration of a semiconductor device according to a first embodiment;

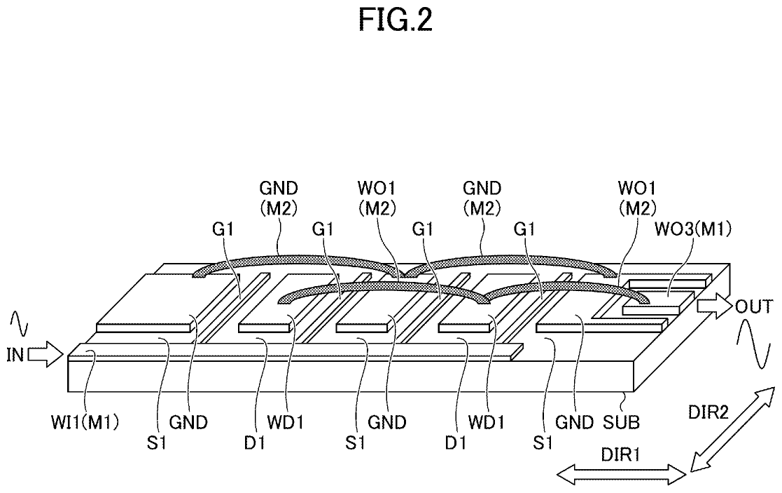

FIG. 2 is a perspective view in which only a main portion of a transistor of the semiconductor device of FIG. 1 is illustrated;

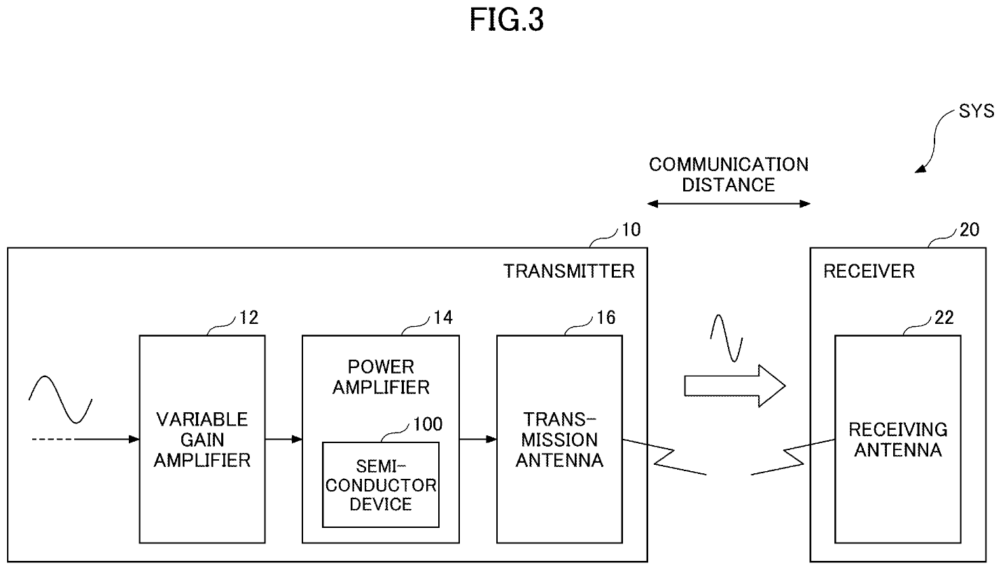

FIG. 3 is a system configuration diagram illustrating an example of a communication system including a power amplifier on which the semiconductor device of FIG. 1 is mounted;

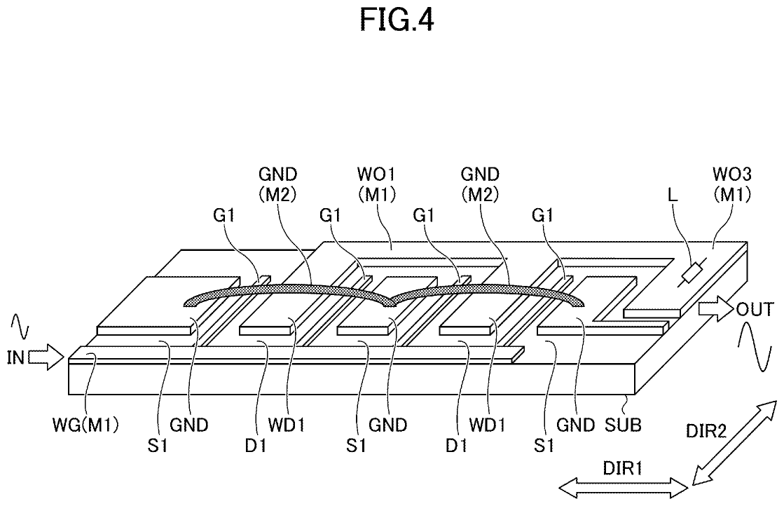

FIG. 4 is a perspective view of another semiconductor device (a comparative example) having a finger-gate type transistor structure substantially the same as that of the semiconductor device of FIG. 1;

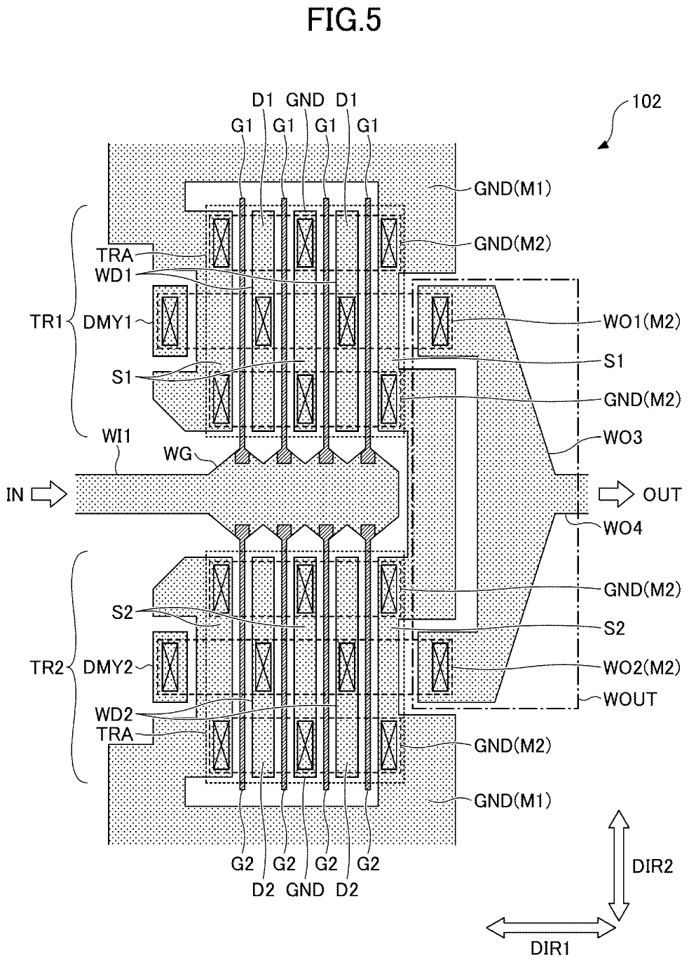

FIG. 5 is a layout diagram illustrating an example of a circuit configuration of a semiconductor device according to a second embodiment;

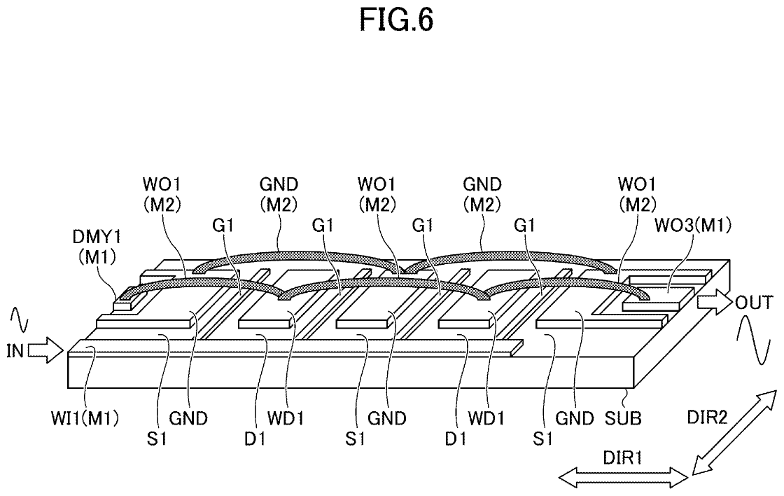

FIG. 6 is a perspective view in which only a main portion of a transistor of the semiconductor device of FIG. 5 is illustrated;

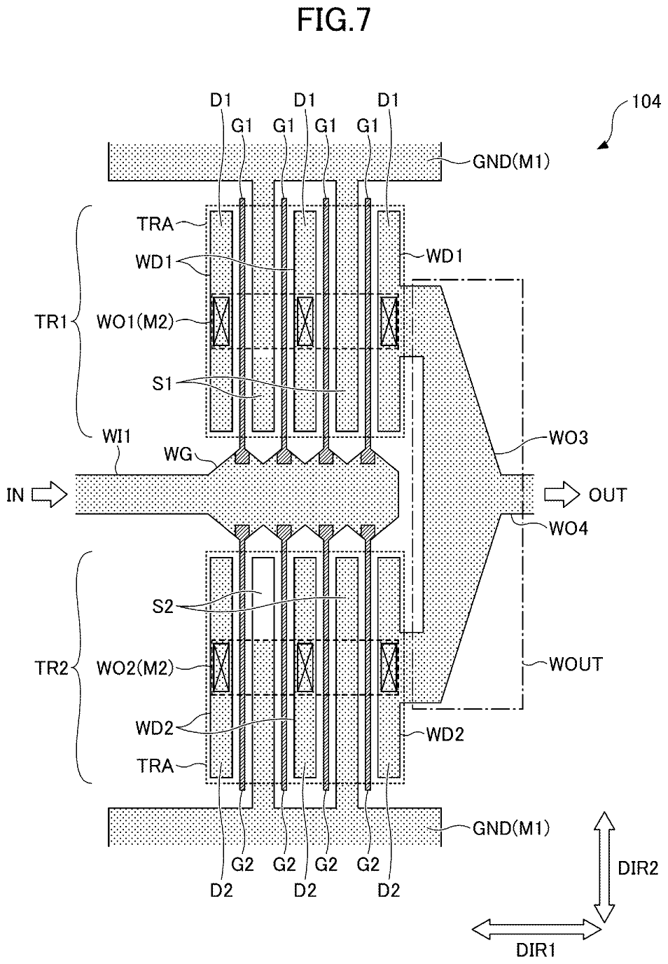

FIG. 7 is a layout diagram illustrating an example of a circuit configuration of a semiconductor device according to a third embodiment; and

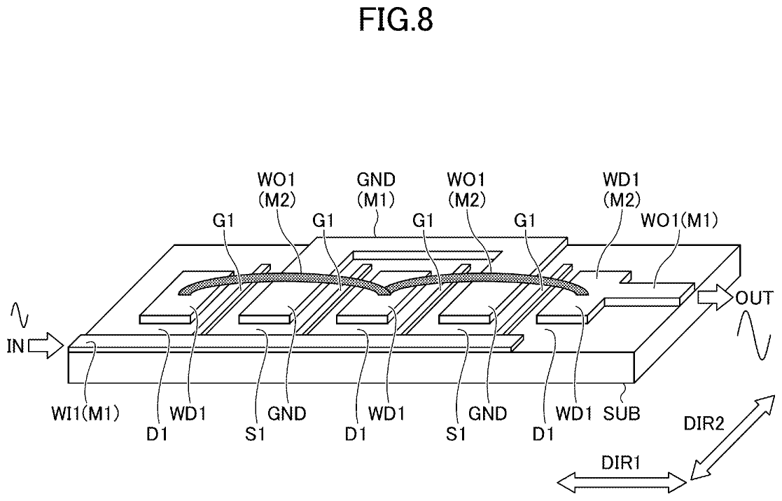

FIG. 8 is a perspective view in which only a main portion of a transistor of the semiconductor device of FIG. 7 is illustrated.

### DETAILED DESCRIPTION

### Description of Embodiments of the Present Disclosure

First, embodiments of the present disclosure will be listed and described.

(1) A semiconductor device according to one aspect of the present disclosure includes a gate wiring line that is connected to an input wiring line connected to an input terminal and that extends in a first direction, a first transistor and a second transistor disposed on both sides of the gate wiring line, along a second direction orthogonal to the first direction, and a signal combining wiring line that connects an output of the first transistor and an output of the second transistor to an output terminal. Each of the first transistor and the second transistor includes a plurality of gate electrodes that are connected to the gate wiring line and that extend in the second direction, and one or more source regions and one or more drain regions arrayed in the first direction with each of the plurality of gate electrodes being interposed between a corresponding source region among the one or more source regions and a corresponding drain region among the one or more drain regions, one or more source wiring lines that are respectively disposed on the one or more source regions and that are respectively connected to the one or more source regions, and one or more drain wiring lines that are respectively disposed on the one or more drain regions and that are respectively connected to the one or more drain regions. The signal combining wiring line includes a first output wiring line that extends on or above the first transistor in the first direction over at least one of the one or more source wiring lines and at least one of the one or more gate electrodes and that is connected to the one or more drain wiring lines of the first transistor, a second output wiring line that extends on or above the second transistor in the first direction over at least one of the one or more source wiring lines and at least one of the one or more gate electrodes and that is connected to the one or more drain wiring lines of the second transistor, a third output wiring line that connects one end of the first output wiring line in the first direction and one end of the second output wiring line in the first direction, and a fourth output wiring line that connects the third output wiring line to the output terminal.

In this semiconductor device, first and second output wiring lines of the signal combining wiring line respectively extends on or above the first and second transistors over the source wiring line and the gate electrode, and are respectively connected to the drain regions of the first and second transistors via drain wiring lines. This can shorten the electrical length of the third output wiring line that connects one end of the first output wiring line and one end of the second output wiring line. As a result, loss of the output signal from the semiconductor device can be reduced, and the output power of the semiconductor device can be increased. In other words, by reducing the size of the signal combining wiring line connected to the drain that is the output of the transistor, loss of the output signal can be reduced and the output power can be increased. Further, the circuit size of the matching circuit connected to the output terminal can be reduced, and the size of the semiconductor device can be reduced.

(2) In (1), the semiconductor device may include a first dummy wiring line disposed on an outside of the first transistor and near another end of the first output wiring line in the first direction, and a second dummy wiring line disposed on an outside of the second transistor and near another end of the second output wiring line in the first direction. The another end of the first output wiring line may extend to the outside of the first transistor and may be connected to the first dummy wiring line, and the another end of the second output wiring line may extend to the outside of the second transistor and may be connected to the second dummy wiring line. By respectively connecting, to the dummy wiring lines, the ends of the first and second output wiring lines on the side opposite to the connection portion with the third output wiring line, the symmetry of the parasitic capacitance due to the first and second output wiring lines connected to respective drain regions via corresponding drain wiring lines can be obtained. This compensation circuit has a plurality of impedances of the drain electrodes similarly to the multi-finger type transistor and the fishbone type transistor. This compensation circuit equalizes the impedances of the drain electrodes, and reduces impedance mismatch. As a result, the proposed transistor shape can improve the output power and the gain.

(3) In (1), in each of the first transistor and the second transistor, the drain region may be formed at an end opposite to the third output wiring line. In this case, the symmetry of the parasitic capacitance due to the first and second output wiring lines connected to respective drain regions via corresponding drain wiring lines can be obtained without connecting dummy wiring lines to the first and second output wiring lines, and high-frequency characteristics can be improved.

(4) In any one of (1) to (3), the source wiring line and the drain wiring line may be formed using a first metal wiring layer, and the first output wiring line and the second output wiring line may have an air-bridge wiring structure formed using a second metal wiring layer that is an upper layer on or above the first metal wiring layer. In this case, because an insulating film is not provided under the first output wiring line and the second output wiring line, a wiring load can be reduced and high-frequency characteristics can be improved.

(5) In any one of (1) to (4), the first output wiring line may be connected to a central portion of the drain wiring line of the first transistor in the second direction, and the second output wiring line may be connected to a central portion of the drain wiring line of the second transistor in the second direction. As a result, the third output wiring line can be shortened and the electrical length can be shortened compared to a case in which the first and second output wiring lines are disposed on the opposite side of the gate wiring lines of the first and second transistors. As a result, loss of the output signal from the semiconductor device can be reduced, and the output power of the semiconductor device can be increased.

(6) A power amplifier according to one aspect of the present disclosure includes the semiconductor device according to any one of (1) to (5). When any one of the semiconductor devices is mounted on a power amplifier, a communication distance of a radio signal transmitted from a transmitter on which the power amplifier is mounted can be increased, for example. As a result, the distance between the transmitter and the receiver can be increased.

### Details of Embodiments of the Present Disclosure

Specific examples of a semiconductor device according to the present disclosure will be described below with reference to the drawings. Note that the present embodiment is not limited to the following description. For example, at least two gate electrodes may be provided in one transistor region TRA, and the number of gate electrodes is not limited to the number illustrated in each drawing.

### First Embodiment

[Layout of Semiconductor Device]

FIG. 1 is a layout diagram illustrating an example of a circuit configuration of a semiconductor device according to a first embodiment. For example, a semiconductor device 100 illustrated in FIG. 1 is mounted on a power amplifier of a millimeter wave band (several tens of GHz to several hundreds of GHz) and is used to amplify power of a high-frequency signal.

Semiconductor device 100 includes transistors TR1 and TR2 that amplify a high-frequency input signal supplied to a common input terminal IN and output an amplified high-frequency output signal from a common output terminal OUT. Transistors TR1 and TR2 are arranged side by side along a direction DIR2. For example, each of transistors TR1 and TR2 is a gallium nitride high electron mobility transistor (GaN HEMT). Each of transistors TR1 and TR2 is formed in transistor region TRA indicated by a dotted rectangle. Although not particularly limited, for example, a gate length of each of transistors TR1 and TR2 is 100 nm (nanometers), and a gate width of each of transistors TR1 and TR2 is 60 μm (microns).

Transistor TR1 includes four gate electrodes G1 extending in direction DIR2, and source regions S1 and drain regions D1 that are alternately provided along a direction DIR1 orthogonal to direction DIR2 with respect to respective gate electrodes G1. Direction DIR1 is an example of a first direction, and direction DIR2 is an example of a second direction. Each of gate electrodes G1 is formed using a first metal wiring layer M1. In the example illustrated in FIG. 1, in transistor region TRA in which transistor TR1 is formed, source regions S1 are formed near both ends in direction DIR1. Transistor TR1 includes three source regions S1 and two drain regions D1 that are alternately provided.

On source region S1, a ground wiring line GND formed using first metal wiring layer M1 is directly connected to source region S1. Ground wiring line GND formed on source region S1 is an example of a source wiring line and a source electrode. A drain wiring line (drain electrode) WD1 formed using first metal wiring layer M1 is directly connected to a drain region D1. First metal wiring layer M1 is a metal wiring layer closest to a semiconductor substrate on which semiconductor device 100 is formed.

Each of ground wiring lines GND formed on source regions S1 is connected to ground wiring lines GND extending in direction DIR1 near both ends in direction DIR2. Ground wiring line GND extending in direction DIR1 is formed using a second metal wiring layer M2. Second metal wiring layer M2 is a metal wiring layer provided on or above first metal wiring layer M1 in semiconductor device 100.

Drain wiring line WD1 famed on drain region D1, directly connected to drain region D1 and extending in direction DIR2 is connected to an output wiring line WO1 extending in direction DIR1. Output wiring line WO1 is formed using second metal wiring layer M2 and is connected to the central portion in direction DIR2 in each drain wiring line WD1. Output wiring line WO1 has what is called an air-bridge wiring structure, and is provided above gate electrode G1 and above ground wiring line GND provided on source region S1 without an interlayer insulating film interposed therebetween. One end of output wiring line WO1 on an output terminal OUT side is connected to one end of an output wiring line WO3 formed by using first metal wiring layer M1.

Transistor TR2 includes four gate electrodes G2 extending in direction DIR2, and source regions S2 and drain regions D2 that are alternately provided along direction DIR1 with respect to respective gate electrodes G2. Gate electrode G2 is formed using first metal wiring layer M1. Similarly to transistor TR1, source regions S2 are formed near both ends in direction DIR1 in another transistor region TRA in which transistor TR2 is formed. Transistor TR2 includes three source regions S2 and two drain regions D2 that are alternately provided.

On source region S2, ground wiring line GND formed using first metal wiring layer M1 is directly connected to source region S2. Ground wiring line GND formed on source region S2 is an example of the source wiring line and the source electrode. A drain wiring line (drain electrode) WD2 formed using first metal wiring layer M1 is directly connected to a drain region D2. Each of ground wiring lines GND formed on source regions S2 is connected to ground wiring lines GND extending in direction DIR1 near both ends in direction DIR2. Ground wiring line GND extending in direction DIR1 is formed using second metal wiring layer M2.

Drain wiring line WD2 formed on drain region D2, directly connected to drain region D2 and extending in direction DIR2 is connected to an output wiring line WO2 extending in direction DIR1. Output wiring line WO2 is formed using second metal wiring layer M2 and is connected to the central portion in direction DIR2 in each drain wiring line WD2. Similarly to output wiring line WO1, output wiring line WO2 has an air-bridge wiring structure, and is provided above gate electrode G2 and above ground wiring line GND provided on source region S2 without an interlayer insulating film interposed therebetween. One end of output wiring line WO2 on the output terminal OUT side is connected to the other end of output wiring line WO3. Thus, output wiring lines WO1 and WO2 are connected to each other via output wiring line WO3.

Output wiring line WO3 is electrically connected to output terminal OUT through an output wiring line WO4 formed by using first metal wiring layer M1. Output wiring lines WO3 and WO4 indicated by a dashed-dotted frame function as a signal combining wiring line WOUT that combines output signals respectively output from drain region D1 of transistor TR1 and drain region D2 of transistor TR2.

Gate electrodes G1 and G2 are connected to each other via a gate wiring line WG. Gate wiring line WG is electrically connected to an input terminal IN via an input wiring line WI1. That is, semiconductor device 100 foims a fishbone type transistor. Further, for example, gate wiring line WG and input wiring line WI1 are famed using first metal wiring layers M1. Gate wiring line WG and input wiring line WI1 may be integrally formed.

By connecting output wiring line WO1 to the central portion in direction DIR2 in each drain wiring line WD1, and connecting output wiring line WO2 to the central portion in direction DIR2 in each drain wiring line WD2, the length of output wiring line WO3 in direction DIR2 can be minimized. This can minimize the electrical length of output wiring line WO3 in direction DIR2. Further, the phase shift of the output signals transmitted to output wiring lines WO1 and WO2 can be reduced.

As a result, loss of the output signal from semiconductor device 100 can be reduced, and the output power of semiconductor device 100 can be increased. In other words, by reducing the size of signal combining wiring line WOUT connected to the drains that are the outputs of transistors TR1 and TR2, loss of output signals can be reduced and the output power can be increased.

Further, the wiring length of signal combining wiring line WOUT can be shortened, and output wiring lines WO1 to WO4 are laid out line-symmetrically with respect to direction DIR1, so that the phase shift of the high-frequency output signals respectively output from drain regions D1 and D2 can be minimized.

[Extraction of Signal from Drain to Output Terminal]

FIG. 2 is a perspective view in which only a main portion of transistor TR1 of semiconductor device 100 illustrated in FIG. 1 is illustrated. In particular, FIG. 2 is a perspective view illustrating an outline of output wiring line WO1 that is second metal wiring layer M2 connected to one end of output wiring line WO3 from drain wiring line WD1 on drain region D1, and illustrating an outline of GND wiring that is second metal wiring layer M2 connecting ground wiring lines GND on multiple source regions S1. As described in the explanation about FIG. 1, each drain region D1 is connected to output wiring line WO3 via output wiring line WO1 having an air-bridge wiring structure. Therefore, air gaps are formed between output wiring line WO1 and gate electrode G1 that faces output wiring line WO1 and between output wiring line WO1 and ground wiring line GND that faces output wiring line WO1. Similarly, an air gap is formed under the GND wiring that is second metal wiring layer M2.

This allows the central portion of each drain wiring line WD1 to be linearly connected to output wiring line WO3. Therefore, wiring resistances and load capacitances of output wiring lines WO1 and WO3 through which the output signal of transistor TR1 is transmitted can be minimized, and deterioration of the high-frequency characteristics of the output signal can be prevented. The structure of output wiring line WO2 connected to drain wiring line WD2 of transistor TR2 in FIG. 1 is substantially the same as the structure of output wiring line WO1 in FIG. 2, and substantially the same effect can be obtained.

For example, semiconductor device 100 includes a gallium nitride (GaN) layer, an aluminum gallium nitride (AlGaN) layer, and a gallium nitride layer that are stacked on a silicon carbide (SiC) substrate. A gold (Au) layer is formed on the back surface of the silicon carbide substrate as a ground layer.

Gate electrodes G1 and G2, ground wiring lines GND, and drain wiring lines WD1 and WD2 are formed on the uppermost gallium nitride layer by using first metal wiring layer M1. For example, gate electrodes G1 and G2, ground wiring lines GND, and drain wiring lines WD1 and WD2 are formed of gold (Au).

Gate electrodes G1 and G2 are Schottky-connected to the gallium nitride layer. Gate electrodes G1 and G2 may have a recess structure. In transistor region TRA, ground wiring lines GND on source regions S1 and S2 and drain wiring lines WD1 and WD2 on drain regions D1 and D2 are in ohmic contact with the gallium nitride layer.

[Communication System in which Semiconductor Device is Mounted]

FIG. 3 is a system configuration diagram illustrating an example of a communication system SYS including a power amplifier in which semiconductor device 100 of FIG. 1 is mounted. Communication system SYS includes a transmitter 10 that wirelessly transmits a high-frequency signal and a receiver 20 that receives the high-frequency signal transmitted from transmitter 10. For example, transmitter 10 and receiver 20 are mounted on a base station of a mobile phone.

Transmitter 10 includes a variable gain amplifier 12, a power amplifier 14, and a transmission antenna 16. Receiver 20 includes a receiving antenna 22 and a receiving circuit (not illustrated). For example, variable gain amplifier 12 generates an output signal by changing a gain of an input signal in accordance with a control voltage and outputs the generated output signal to power amplifier 14.

Power amplifier 14 amplifies the power of the signal received from variable gain amplifier 12 and outputs the amplified signal to transmission antenna 16. Transmission antenna 16 converts an electric signal received from power amplifier 14 into a radio wave and transmits the radio wave to receiver 20. Receiver 20 receives radio waves from transmitter 10 through receiving antenna 22 and performs signal processing.

In a base station of a mobile phone, as the output power of the signal transmitted by transmitter 10 increases, the communication distance between the base stations can be increased. By increasing the communication distance, the installation interval of the base stations can be increased. Therefore, it is important to improve the output power of semiconductor device 100.

[Extraction of Signal from Drain to Output Terminal of Another Semiconductor Device]

FIG. 4 is a perspective view of another semiconductor device (comparative example) having a finger-gate type transistor structure substantially the same as that of semiconductor device 100 of FIG. 1. FIG. 4 is a perspective view in which only a main portion corresponding to transistor TR1 as in FIG. 2 is illustrated. In FIG. 4, output wiring line WO1 is formed using first metal wiring layer M1, similarly to gate wiring line WG, rather than using the air-bridge wiring structure. For this reason, output wiring line WO1 is formed at a position where ground wiring line GND famed on source region S1 can be bypassed.

Because output wiring line WO1 is formed by bypassing ground wiring line GND, the electrical length of output wiring line WO3 is longer than that in FIG. 2, and the band of output signals is narrowed due to unnecessary reactance components L. In addition, because output wiring line WO3 is long, the circuit size of the matching circuit connected to output terminal OUT becomes large.

As described above, in this embodiment, output wiring lines WO1 and WO2 have the air-bridge wiring structure, are formed over ground wiring lines GND on source regions S1 and gate electrodes G1 and G2, and are connected to output wiring line WO3. For example, output wiring line WO1 is connected to the central portion in direction DIR2 in each drain wiring line WD1, and output wiring line WO2 is connected to the central portion in direction DIR2 in each drain wiring line WD2.

This can minimize the electrical length in direction DIR2 of output wiring line WO3. Further, the phase shift of the output signals transmitted to output wiring lines WO1 and WO2 can be reduced. As a result, impedance and loss of the output signal from semiconductor device 100 can be reduced, and the output power of semiconductor device 100 can be increased. In addition, by reducing the impedance, the circuit size of a matching circuit (not illustrated) connected to output terminal OUT of semiconductor device 100 can be reduced, and the size of semiconductor device 100 can be reduced. Further, because output wiring lines WO1 and WO2 have the air-bridge wiring structure, the wiring load can be reduced and the high-frequency characteristics can be improved.

By mounting semiconductor device 100 on power amplifier 14 of transmitter 10 of communication system SYS, the communication distance to receiver 20 can be increased. For example, when transmitter 10 and receiver 20 are mounted on a base station of a mobile phone, the communication distance between the base stations can be increased. As a result, the installation interval of the base stations can be increased, and the equipment cost of communication system SYS can be reduced.

### Second Embodiment

[Layout of Semiconductor Device]

FIG. 5 is a layout diagram illustrating an example of a circuit configuration of a semiconductor device according to a second embodiment. Elements substantially the same as those in FIG. 1 are denoted by the same reference numerals, and detailed description thereof will be omitted. A semiconductor device 102 illustrated in FIG. 5 has substantially the same structure as semiconductor device 100 illustrated in FIG. 1 except that output wiring lines WO1 and WO2 are different from output wiring lines WO1 and WO2 illustrated in FIG. 1.

With respect to output wiring line WO1, an end opposite to output wiring line WO3 in direction DIR1 extends to the outside of transistor region TRA and is connected to a dummy wiring line DMY1 disposed outside transistor region TRA. With respect to output wiring line WO2, an end opposite to output wiring line WO3 in direction DIR1 extends to the outside of another transistor region TRA and is connected to a dummy wiring line DMY2 disposed outside another transistor region TRA.

For example, dummy wiring lines DMY1 and DMY2 are formed using first metal wiring layer M1. Dummy wiring line DMY1 is not electrically connected to anything other than output wiring line WO1, and dummy wiring line DMY2 is not electrically connected to anything other than output wiring line WO2.

For example, the distance between drain wiring line WD1 on the left side of FIG. 5 and dummy wiring line DMY1 is equal to the distance between two drain wiring lines WD1 and equal to the distance between drain wiring line WD1 on the right side of FIG. 5 and output wiring line WO3. The distance between drain wiring line WD2 on the left side of FIG. 5 and dummy wiring line DMY2 is equal to the distance between two drain wiring lines WD2 and equal to the distance between drain wiring line WD2 on the right side of FIG. 5 and output wiring line WO3. Therefore, output wiring line WO1 has symmetry with respect to respective drain wiring lines WD1, and output wiring line WO2 has symmetry with respect to respective drain wiring lines WD2.

[Symmetry of Output Wiring Line]

FIG. 6 is a perspective view in which only a main portion of transistor TR1 of semiconductor device 102 of FIG. 5 is illustrated. In particular, FIG. 6 is a perspective view illustrating an outline of output wiring line WO1 connected to drain wiring lines WD1 of transistor TR1. Each drain region D1 is connected to output wiring line WO3 via output wiring line WO1 having an air-bridge wiring structure. In this case, one end of output wiring line WO1 is connected to output wiring line WO3, and the other end of output wiring line WO1 is connected to dummy wiring line DMY1.

Therefore, the partial wiring of output wiring line WO1 extending toward both sides in direction DIR1 with respect to each drain wiring line WD1 and connected to adjacent drain wiring line WD1 and output wiring line WO3 (or dummy wiring line DMY1) can be symmetrical. The partial wiring of output wiring line WO2 extending toward both sides in direction DIR1 with respect to each drain wiring line WD2 can also be symmetrical similarly to output wiring line WO1.

As a result, the symmetry of the parasitic capacitance due to output wiring line WO1 connected to respective drain regions D1 via drain wiring lines WD1 can be obtained, and the high-frequency characteristics can be improved. In addition, the symmetry of the parasitic capacitance due to output wiring line WO2 connected to respective drain regions D2 via drain wiring lines WD2 can be obtained, and the high-frequency characteristics can be improved.

When the number of gate electrodes G1 is an odd number (for example, three) and gate electrode G1 and source region S1 on the leftmost side of FIG. 6 are not formed, dummy wiring line DMY1 is arranged at the position illustrated in FIG. 6. Output wiring line WO1 is connected to dummy wiring line DMY1. The same applies to a case where the number of gate electrodes G2 of transistor TR2 is an odd number. This enables the symmetry of the parasitic capacitance due to output wiring lines WO1 and W02, regardless of the numbers of gate electrodes G1 and G2, to be obtained.

As described above, also in this embodiment, substantially the same effects as those of the above-described embodiment can be obtained. Further, in this embodiment, with respect to output wiring lines WO1 and W02, the ends opposite to the connecting portions with output wiring line WO3 are respectively connected to dummy wiring line DMY1 and DMY2. As a result, the symmetry of the parasitic capacitance due to output wiring lines WO1 and WO2 connected to respective drain regions D1 and D2 via drain wiring lines WD1 and WD2 can be obtained, thereby improving the high-frequency characteristics.

### Third Embodiment

[Layout of Semiconductor Device]

FIG. 7 is a layout diagram illustrating an example of a circuit configuration of a semiconductor device according to a third embodiment. Elements substantially the same as those in FIG. 1 are denoted by the same reference numerals, and detailed description thereof will be omitted. In a semiconductor device 104 illustrated in FIG. 7, the arrangement order of source region S1 and drain region D1 in transistor TR1 is different from that in FIG. 1. Further, in transistor TR2, the arrangement order of source region S2 and drain region D2 is different from that in FIG. 1. FIG. 7 illustrates a case where the number of gate electrodes G1 and the number of gate electrodes G2 are even numbers.

In transistor TR1, three drain regions D1 are formed at both ends and the center in direction DIR1, and each source region S1 is formed between two drain regions D1. Drain wiring line WD1 disposed on each drain region D1 is connected to corresponding drain region D1. Ground wiring line GND disposed on each source region S1 is connected to corresponding source region S1. Ground wiring line GND on source region S1 is connected to ground wiring line GND disposed on the opposite side of transistor TR2 outside transistor region TRA.

In transistor TR2, three drain regions D2 are formed at both ends and the center in direction DIR1, and each source region S2 is famed between two drain regions D2. Drain wiring line WD2 disposed on each drain region D2 is connected to corresponding drain region D2. Ground wiring line GND disposed on each source region S2 is connected to corresponding source region S2. Ground wiring line GND on source region S2 is connected to ground wiring line GND disposed on the opposite side of transistor TR1 outside another transistor region TRA.

In this embodiment, output wiring line WO1 is connected to each of drain wiring lines WD1 on drain regions D1 located at both ends and the center in direction DIR1. Output wiring line WO1 is connected to output wiring line WO3 via drain wiring line WD1 closest to output wiring line WO3. Output wiring line WO2 is connected to each of drain wiring lines WD2 on drain regions D2 located at both ends and the center in direction DIR1. Output wiring line WO2 is connected to output wiring line WO3 via drain wiring line WD2 closest to output wiring line WO3.

[Symmetry of Output Wiring Line]

FIG. 8 is a perspective view in which only a main portion of transistor TR1 of semiconductor device 104 of FIG. 7 is illustrated. In particular, FIG. 8 is a perspective view illustrating an outline of output wiring line WO1 connected to drain wiring lines WD1. As illustrated in FIG. 8, when the number of gate electrodes G1 is an even number and drain regions D1 are formed near both ends in direction DIR1, the symmetry of parasitic capacitance due to output wiring line WO1 connected to drain regions D1 can be obtained without forming dummy wiring line DMY1 illustrated in FIG. 6. Similarly, with respect to output wiring line WO2 of transistor TR2, the symmetry of the parasitic capacitance can be obtained.

When there are three gate electrodes G1 and leftmost gate electrode G1 and drain region D1 in FIG. 8 are not formed, dummy wiring line may be famed instead of leftmost drain wiring line WD1 in FIG. 8.

As described above, also in this embodiment, substantially the same effects as those of the above-described embodiments can be obtained. Furthermore, in this embodiment, the symmetry of the parasitic capacitance due to output wiring lines WO1 and WO2 connected to drain regions D1 and D2 without forming dummy wiring lines DMY1 and DMY2 illustrated in FIG. 6 can be obtained, thereby improving the high-frequency characteristics of the output signals.

Although the embodiments and the like of the present disclosure have been described above, the present disclosure is not limited to the above-described embodiments and the like. Various changes, modifications, substitutions, additions, deletions, and combinations are possible within the scope of the claims. These also naturally belong to the technical scope of the present disclosure.

What is claimed is:

1. A semiconductor device comprising:
a gate wiring line that is connected to an input wiring line connected to an input terminal, the gate wiring line extending in a first direction;
a first transistor and a second transistor disposed on both sides of the gate wiring line, along a second direction orthogonal to the first direction; and
a signal combining wiring line that connects an output of the first transistor and an output of the second transistor to an output terminal,
wherein each of the first transistor and the second transistor includes
a plurality of gate electrodes connected to the gate wiring line, the plurality of gate electrodes extending in the second direction,
one or more source regions and one or more drain regions arrayed in the first direction with each of the plurality of gate electrodes being interposed between a corresponding source region among the one or more source regions and a corresponding drain region among the one or more drain regions,
one or more source wiring lines respectively disposed on the one or more source regions, the one or more source wiring lines being respectively connected to the one or more source regions, and
one or more drain wiring lines respectively disposed on the one or more drain regions, the one or more drain wiring lines being respectively connected to the one or more drain regions, and
wherein the signal combining wiring line includes
a first output wiring line that extends on or above the first transistor in the first direction over at least one of the one or more source wiring lines and at least one of the plurality of gate electrodes, the first output wiring line being connected to the one or more drain wiring lines of the first transistor,
a second output wiring line that extends on or above the second transistor in the first direction over at least one of the one or more source wiring lines and at least one of the plurality of gate electrodes, the second output wiring line being connected to the one or more drain wiring lines of the second transistor,
a third output wiring line that connects one end of the first output wiring line in the first direction and one end of the second output wiring line in the first direction, and
a fourth output wiring line that connects the third output wiring line to the output terminal.

2. The semiconductor device according to claim 1, comprising:
a first dummy wiring line disposed on an outside of the first transistor and near another end of the first output wiring line in the first direction; and
a second dummy wiring line disposed on an outside of the second transistor and near another end of the second output wiring line in the first direction,
wherein the another end of the first output wiring line extends to the outside of the first transistor and is connected to the first dummy wiring line, and
wherein the another end of the second output wiring line extends to the outside of the second transistor and is connected to the second dummy wiring line.

3. The semiconductor device according to claim 1,
wherein, in each of the first transistor and the second transistor, a drain region among one or more drain regions is formed at an end opposite to the third output wiring line.

4. The semiconductor device according to claim 1,
wherein the one or more source wiring lines and the one or more drain wiring lines are famed using a first metal wiring layer, and
wherein the first output wiring line and the second output wiring line have an air-bridge wiring structure formed using a second metal wiring layer that is an upper layer on or above the first metal wiring layer.

5. The semiconductor device according to claim 1,
wherein the first output wiring line is connected to a central portion of each of the one or more drain wiring lines of the first transistor in the second direction, and
wherein the second output wiring line is connected to a central portion of each of the one or more drain wiring lines of the second transistor in the second direction.

6. A power amplifier comprising the semiconductor device according to claim 1.
